(19) United States
(12) Patent Application Publication
(10) Pub. No.: US 2013/0327376 A1
(43) Pub. Date: Dec. 12, 2013

(54) SOLAR CELL AND METHOD FOR MANUFACTURING THE SAME

(71) Applicant: SAMSUNG ELECTRONICS CO., LTD., Suwon-si (KR)

(72) Inventors: Xavier BULLIARD, Suwon-si (KR); Youn-Hee LIM, Seoul (KR); Jae-Jun CHANG, Seoul (KR)

(73) Assignee: SAMSUNG ELECTRONICS CO., LTD., Suwon-Si, Gyeonggi-Do (KR)

(21) Appl. No.: 13/667,148

(22) Filed: Nov. 2, 2012

(30) Foreign Application Priority Data
Jun. 8, 2012 (KR) 10-2012-0061550

(51) Int. Cl. H01L 31/02; H01L 31/18; B82Y 99/00

(52) U.S. Cl. 136/252; 438/98; 977/948; 257/E31.124

(57) ABSTRACT

A solar cell includes a first electrode, a second electrode facing the first electrode, an active layer between the first and second electrodes, and an interlayer between the first electrode and the active layer, the interlayer including an amphiphilic fullerene derivative.

### CROSS-REFERENCE TO RELATED APPLICATION

This application claims priority to and the benefit of Korean Patent Application No. 10-2012-0061550 filed in the Korean Intellectual Property Office on Jun. 8, 2012, the entire contents of which are incorporated herein by reference.

### BACKGROUND

1. Field

Example embodiments relate to a solar cell and a method for manufacturing the same.

2. Description of the Related Art

A solar cell is a photoelectric conversion device that transforms solar energy into electrical energy, and has attracted much attention as an infinite but pollution-free next generation energy source.

A solar cell includes p-type and n-type semiconductors and produces electrical energy by transferring electrons and holes to the n-type and p-type semiconductors, respectively, and collecting electrons and holes in each electrode when an electron-hole pair (EHP) is produced by solar light energy absorbed in a photoactive layer inside the semiconductors.

Further, a solar cell is required to have as much efficiency as possible for producing electrical energy from solar energy.

### SUMMARY

Example embodiments provide a solar cell being capable of improving efficiency. Other example embodiments provide a method of manufacturing the solar cell. The solar cell may include an interlayer between a photoactive layer and an electrode in order to effectively absorb light with minimum or relatively little loss so that as many electron-hole pairs as possible may be produced, and then collect the produced charges without loss.

According to example embodiments, a solar cell includes a first electrode, a second electrode facing the first electrode, an active layer between the first electrode and second electrode, and an interlayer between the first electrode and active layer, the interlayer including an amphiphilic fullerene derivative.

The amphiphilic fullerene derivative may be represented by the following Chemical Formula 1.

Z¹-A-Z² [Chemical Formula 1]

In Chemical Formula 1, A is fullerene, Z¹ is a side chain including a hydrophobic functional group, and Z² is a side chain including a hydrophilic functional group.

The fullerene may be represented by C₂ₙ (n≧10) or CₘHₚ (10≦m≦100, 10≦p≦100). The Z¹ and Z² may be positioned to be opposed to each other with respect to an axis of the fullerene.

The hydrophobic functional group may have a polarity more than or equal to about 0 mN/m and less than or equal to about 5 mN/m, and the hydrophilic functional group may have a polarity more than about 5 mN/m and less than or equal to about 50 mN/m.

The hydrophobic functional group may include one of a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, a halogen, a C₁ to C₃₀ ester group, a halogen-containing group, and a combination thereof.

The hydrophilic functional group may include one of a hydroxyl group, an acid group, a carboxylic acid group, a phosphoric acid group, an amino group, a sulfone group, an ammonium group, a substituted or unsubstituted C₁ to C₃₀ alkoxy group, and a combination thereof.

The amphiphilic fullerene derivative may be represented by the following Chemical Formula 1a.

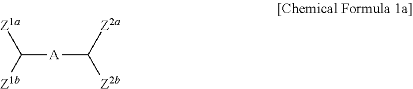

In Chemical Formula 1a, A is fullerene, each of Z^{1a} and Z^{2a} are independently one of a substituted or unsubstituted C₁ to C₃₀ alkyl group, a substituted or unsubstituted C₃ to C₃₀ cycloalkyl group, a substituted or unsubstituted C₆ to C₃₀ aryl group, and a substituted or unsubstituted C₂ to C₃₀ heteroaryl group, Z^{1b} is a side chain including a hydrophobic functional group, and Z^{2b} is a side chain including a hydrophilic functional group.

The amphiphilic fullerene derivative may be represented by the following Chemical Formula 1aa.

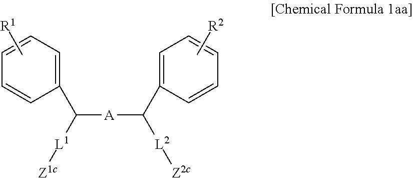

In Chemical Formula 1aa, A is fullerene, each of R¹ and R² are independently one of hydrogen, a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, and a combination thereof, each of L¹ and L² are independently one of a single bond, a substituted or unsubstituted C₁ to C₂₀ alkylene group, a substituted or unsubstituted C₃ to C₂₀ cycloalkylene group, a substituted or unsubstituted C₆ to C₃₀ arylene group, a substituted or unsubstituted C₂ to C₃₀ heteroarylene group, and a combination thereof, Z^{1c} is a side chain including a hydrophobic functional group, and Z^{2c} is a side chain including a hydrophilic functional group.

The amphiphilic fullerene derivative may be self-aligned between the first electrode and the active layer. Z¹ of the amphiphilic fullerene derivative may be self-aligned on a side of the active layer, and Z² of the amphiphilic fullerene derivative may be self-aligned on a side of the first electrode.

The solar cell may further include a buffer layer between the first electrode and the interlayer. The buffer layer may include a metal oxide. Z² of the amphiphilic fullerene derivative may be chemically bonded with the metal oxide.

The first electrode may be a cathode and the second electrode may be an anode. The first electrode may be an anode and the second electrode may be a cathode.

According to example embodiments, a method of manufacturing a solar cell includes providing a first electrode, providing an active layer on the first electrode, providing a second electrode on the active layer, and providing an interlayer including an amphiphilic fullerene derivative between the first electrode and the active layer.

The amphiphilic fullerene derivative may be represented by the above Chemical Formula 1.

The providing an interlayer may include applying a solution including the amphiphilic fullerene derivative on one of the first electrode and the active layer. The solution may include a solvent selected from chloroform, dichloromethane, xylene, toluene, benzene, chlorobenzene, dichlorobenzene, tetrahydrofuran, and a combination thereof.

The method may further include heating the amphiphilic fullerene derivative at about 20° C. to about 150° C. after applying the solution. The method may further include providing a buffer layer after the providing a first electrode and before the providing an interlayer, the buffer layer including a metal oxide.

The providing an interlayer may include applying a solution including the amphiphilic fullerene derivative on the buffer layer, and heating the buffer layer including the applied solution at about 20° C. to about 150° C. A condensation reaction of Z² of the amphiphilic fullerene derivative and the metal oxide may be induced in the heating.

The providing a first electrode may include providing a cathode, and the providing a second electrode may include providing an anode. The providing a first electrode may include providing an anode, and the providing a second electrode may include providing a cathode.

### BRIEF DESCRIPTION OF THE DRAWINGS

These and/or other aspects will become apparent and more readily appreciated from the following description of example embodiments, taken in conjunction with the accompanying drawings of which:

FIG. 1 is a schematic cross-sectional view of a solar cell according to example embodiments.

FIG. 2 is a schematic view showing a self-aligned amphiphilic fullerene derivative in a solar cell according to example embodiments.

FIG. 3 is a schematic cross-sectional view of a solar cell according to example embodiments.

FIG. 4 is a schematic cross-sectional view of a solar cell according to example embodiments.

FIG. 5A is a MALDI-ToF analysis graph of a fullerene derivative product before separation in a synthesis example.

FIG. 5B is a MALDI-ToF analysis graph of fullerene derivative product after separation in a synthesis example.

FIG. 6 is a schematic view of a solar cell according to examples.

### DETAILED DESCRIPTION

Example embodiments will hereinafter be described in detail referring to the following drawings, and can be more easily performed by those who have common knowledge in the related art. However, these embodiments are only examples, and the inventive concepts are not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first”, “second”, etc. may be used herein to describe various elements, components, regions, layers and/or sections, these elements, components, regions, layers and/or sections are not to be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments are not to be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, is to be interpreted as having a meaning that is consistent with their meaning in the context of the relevant art and will not be interpreted in an idealized or overly formal sense unless expressly so defined herein.

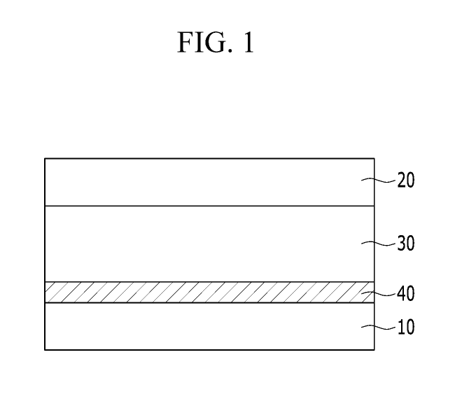

Referring to the drawings, a solar cell according to example embodiments is illustrated. FIG. 1 is a schematic cross-sectional view of a solar cell according to example embodiments. Referring to FIG. 1, a solar cell includes a substrate (not shown), a first electrode 10, e.g., a cathode, a second electrode 20, e.g., an anode, facing the first electrode 10, an active layer 30 between the first electrode 10 and second electrode 20, and an interlayer 40 between the first electrode 10 and the active layer 30.

The substrate may be positioned on the first electrode 10 or second electrode 20, and may be made of a transparent material. The transparent material may include, for example, an inorganic material, e.g., glass and/or an organic material, for example, polycarbonate, polymethylmethacrylate, polyethylene terephthalate, polyethylene naphthalate, polyamide, polyethersulfone, or a combination thereof.

One of the first electrode 10 and the second electrode 20 may be made of a transparent conductor, e.g., indium tin oxide (ITO), indium doped zinc oxide (IZO), tin oxide (SnO₂), aluminum doped zinc oxide (AZO), and/or gallium doped zinc oxide (GZO), and the other may be made of an opaque conductor, e.g., aluminum (Al), silver (Ag), and/or gold (Au).

The active layer 30 may be made of a photoactive material including an electron acceptor made of an n-type semiconductor material and an electron donor made of a p-type semiconductor material.

The electron acceptor and electron donor may form, for example, a bulk heterojunction structure. In the case of the bulk heterojunction structure, when the electron-hole pair excited by light absorbed in the active layer 30 reaches the interface of the electron acceptor and the electron donor by diffusion, electrons and holes are separated by the electron affinity difference of the two materials at the interface. The electrons are moved to a first electrode through the electron acceptor and holes are moved to a second electrode through the electron donor to generate a photocurrent.

The photoactive material may include, for example at least two selected from polyaniline; polypyrrole; polythiophene; poly(p-phenylenevinylene); benzodithiophene; thienothiophene; MEH-PPV (poly(2-methoxy-5-(2′-ethyl-hexyloxy)-1,4-phenylene vinylene); MDMO-PPV (poly(2-methoxy-5-(3,7-dimethyloctyloxy)-1,4-phenylene-vinylene); pentacene; perylene(perylene); poly(3,4-ethylenedioxythiophene) (PEDOT), poly(3-alkylthiophene); poly ((4,8-bis(octyloxy)benzo[1,2-b:4,5-b′]dithiophen)-2,6-diyl-alt-(2-((dodecyloxy)carbonyl) thieno[3,4-b]thiophene)-3,6-diyl) (PTB1); poly((4,8-bis(2-ethylhexyloxy)benzo[1,2-b:4,5-b′]dithiophene)-2,6-diyl-alt-(2-((2-ethylhexyloxy)carbonyl)-3-fluorothieno[3,4-b]thiophenediyl)-3,6-diyl)) (PTB7); phthalocyanine; tin(II) phthalocyanine (SnPc); copper phthalocyanine; triarylamine; benzidine; pyrazoline; styrylamine; hydrazone; carbazole; thiophene; 3,4-ethylenedioxythiophene (EDOT); pyrrole; phenanthrene; tetracene; naphthalene; rubrene; 1,4,5,8-naphthalene-tetracarboxylic dianhydride (NTCDA); Alq₃; fullerene (C₆₀, C₇₀, C₇₄, C₇₆, C₇₈, C₈₂, C₈₄, C₇₂₀, and C₈₆₀); a fullerene derivative, e.g., 1-(3-methoxy-carbonyl)propyl-1-phenyl(6,6)C₆₁ (PCBM), C₇₁-PCBM, C₈₄-PCBM, and/or bis-PCBM; an inorganic semiconductor, e.g., CdS, CdTe, CdSe, and ZnO; derivatives thereof; and copolymers thereof, but is not limited thereto.

When greater than or equal to two kinds of photoactive materials having different energy levels form a bulk heterojunction, the material having a relatively lower LUMO (lowest unoccupied molecular orbital) level is used as the electron acceptor, and the material having a relatively higher LUMO level is used as the electron donor.

The interlayer 40 includes an amphiphilic fullerene derivative. The amphiphilic fullerene derivative is a fullerene or fullerene derivative having both hydrophilicity and hydrophobicity.

The amphiphilic fullerene derivative may be represented by the following Chemical Formula 1.

Z¹-A-Z² [Chemical Formula 1]

In Chemical Formula 1, A is fullerene, Z¹ is a side chain including a hydrophobic functional group, and Z² is a side chain including a hydrophilic functional group.

The fullerene is spherical carbon having a cage-shaped or open structure, and for example, is represented by C₂ₙ (n≧10, for example 10≦n≦1500) or CₘHₚ (10≦m≦100 and 10≦p≦100).

The fullerene includes two side chains (Z¹ and Z²), and the two side chains (Z¹ and Z²) may be positioned to be opposed to each other with respect to an axis of the fullerene. In other words, one side chain may be disposed on one hemisphere of fullerene, and the other side chain may be disposed on the other hemisphere of fullerene.

The two side chains (Z¹ and Z²) may have different surface properties. In other words, Z¹ may be a side chain having a hydrophobic functional group, and Z² may be a side chain having a hydrophilic functional group.

The hydrophobic functional group may have relatively low polarity and the hydrophilic functional group may have relatively high polarity.

The hydrophobic functional group may have polarity of more than or equal to about 0 mN/m and less than or equal to about 5 mN/m, and the hydrophilic functional group may have polarity of more than about 5 mN/m and less than or equal to about 50 mN/m. The hydrophobic functional group may include one of a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, a halogen, a C₁ to C₃₀ ester group, a halogen-containing group, and a combination thereof.

The hydrophilic functional group may include one of a hydroxyl group, an acid group, e.g., a carboxylic acid group, a phosphoric acid group, an amino group, a sulfone group, an ammonium group, a substituted or unsubstituted C₁ to C₃₀ alkoxy group, and a combination thereof.

The hydrophilic functional group may be bonded to, for example, one of an aliphatic and/or aromatic group, e.g., an alkyl group, a cycloalkyl group, an aryl group, and a heteroaryl group.

The amphiphilic fullerene derivative may be represented by the following Chemical Formula 1a.

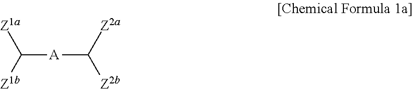

In Chemical Formula 1a, A is fullerene, each of Z^{1a} and Z^{2a} are independently one of a substituted or unsubstituted C₁ to C₃₀ alkyl group, a substituted or unsubstituted C₃ to C₃₀ cycloalkyl group, a substituted or unsubstituted C₆ to C₃₀ aryl group, and a substituted or unsubstituted C₂ to C₃₀ heteroaryl group, Z^{1b} is a side chain including a hydrophobic functional group, and Z^{2b} is a side chain including a hydrophilic functional group.

The amphiphilic fullerene derivative may be represented by the following Chemical Formula 1aa.

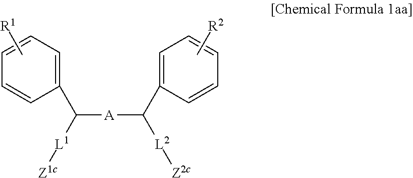

In Chemical Formula 1aa, A is fullerene, each of R¹ and R² are independently one of hydrogen, a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, and a combination thereof,

each of L¹ and L² are independently one of a single bond, a substituted or unsubstituted C₁ to C₂₀ alkylene group, a substituted or unsubstituted C₃ to C₂₀ cycloalkylene group, a substituted or unsubstituted C₆ to C₃₀ arylene group, a substituted or unsubstituted C₂ to C₃₀ heteroarylene group, and a combination thereof, Z^{1c} is a side chain including a hydrophobic functional group, and Z^{2c} is a side chain including a hydrophilic functional group.

The amphiphilic fullerene derivative represented by the above Chemical Formula 1aa may be, for example, a compound represented by the following Chemical Formula 1aa-1.

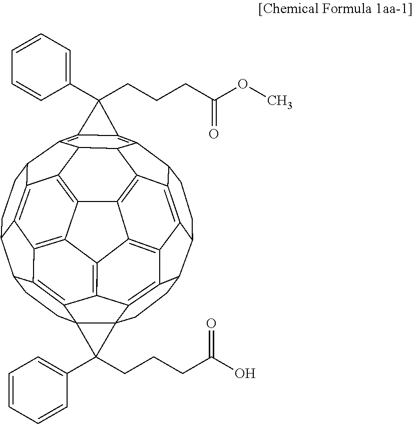 [SMILES: COC(=O)CCCC1(c2ccccc2)C2=C3C4CCC5c6c4c4c7c8c6c6c9c%10c%11c%12c%13c%14c%15c(c-7c%13c%108)C(C(=C21)C%15CCC%14C%12CCC%111C(CCCC(=O)O)(c2ccccc2)C91CCC65)C34]

In the amphiphilic fullerene derivative represented by the above Chemical Formula 1aa-1, the fullerene is C₆₀, a terminal end of one side chain is a methyl ester group, and a terminal end of another side chain is a carboxylic acid group.

The amphiphilic fullerene derivative may be self-aligned between the first electrode 10 and the active layer 30 due to a difference between the surface properties. Z¹ of the amphiphilic fullerene derivative may be self-aligned on a side of the active layer, and Z² of the amphiphilic fullerene derivative may be self-aligned on a side of the first electrode.

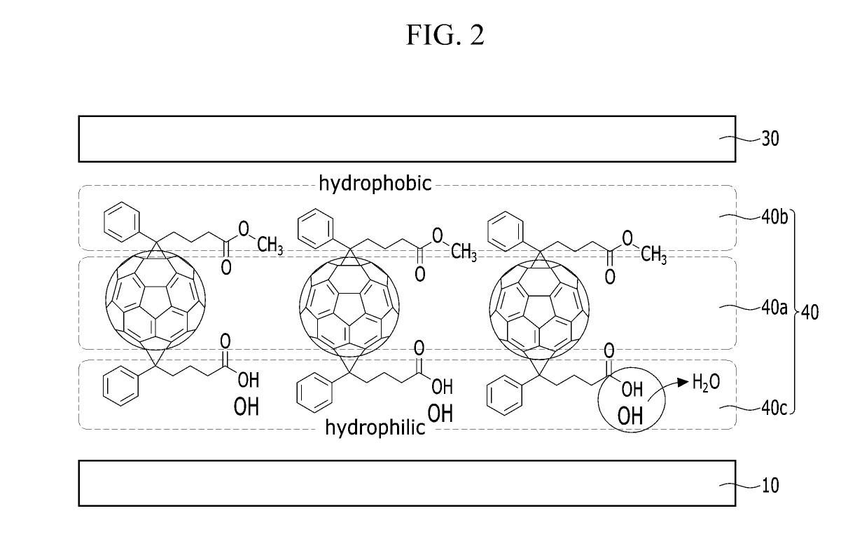

The above description will be explained referring to FIG. 2. FIG. 2 is a schematic view showing a self-aligned amphiphilic fullerene derivative in a solar cell according to example embodiments. Referring to FIG. 2, the amphiphilic fullerene derivative may be aligned in a line on the first electrode 10 to form the interlayer 40. The interlayer 40 may include a core area 40a in which fullerene is aligned in a line, a coupling area 40b disposed on the side of active layer 30 in which the side chain having the hydrophobic functional group is aligned in a line, and an anchor area 40c disposed on the side of the first electrode 10 in which the side chain having the hydrophilic functional group is aligned in a line.

The core area 40a decreases an energy barrier when electrons produced in the active layer 30 are moved to the first electrode 10 by including fullerene to mediate forward charge transfer and reduce back charge recombination at the interface. On the other hand, a loss of holes due to recombination may be prevented or reduced by blocking the transportation of holes produced in the active layer 30 to the first electrode 10. Accordingly, the efficiency of a solar cell may be increased.

The coupling area 40b may control electrical coupling of n-type semiconductor materials of the active layer 30 and the surface energy of interlayer 40, as well as increase the compatibility between the active layer 30 and the interlayer 40 by aligning the hydrophobic functional group similar to the n-type semiconductor material of the active layer 30.

The anchor area 40c forms a physical bond or a chemical bond by condensation with a hydroxyl group (—OH) which is naturally present on the metal oxide surface disposed on the lower layer, so as to be firmly fixed on the side of first electrode 10 to provide mechanical stability.

As stated above, as the interlayer 40 is disposed between the first electrode 10 and the active layer 30, the charge transport may be improved by improving the compatibility with the active layer 30 and the mechanical stability with the first electrode 10 as well as improving the efficiency due to the selective charge transport characteristics of fullerene. Accordingly, the efficiency of a solar cell may be improved.

A method of manufacturing the above solar cell is described referring to FIG. 1. The method of manufacturing a solar cell according to example embodiments includes providing the first electrode 10, e.g., a cathode, providing the active layer 30 on the first electrode 10, providing the second electrode 20, e.g., an anode, on the active layer 30, and providing the interlayer 40 including an amphiphilic fullerene derivative between the first electrode 10 and the active layer 30.

The first electrode 10 may be a cathode and the second electrode 20 may be an anode, or vice versa. The order of providing the cathode and providing the anode may be shifted according to the structure of the solar cell. For example, in the case of a solar cell having a structure in which the cathode is the second electrode 20 disposed on the upper part of the solar cell, the anode may be the first electrode 10 provided before the cathode, while in the case of a solar cell having a structure in which the cathode is the first electrode 10 disposed on the lower part of the solar cell, the anode may be the second electrode 20 provided after the cathode.

The first electrode 10 and the second electrode 20 may be made of, for example, a transparent conductor, e.g., indium tin oxide (ITO), indium doped zinc oxide (IZO), tin oxide (SnO₂), aluminum doped zinc oxide (AZO), and/or gallium doped zinc oxide (GZO), or an opaque conductor, e.g., aluminum (Al), silver (Ag), gold (Au), and/or lithium (Li), using, for example, sputtering or deposition, respectively. The first electrode 10 and the second electrode 20 may be made in a single layer or in multiple layers.

Providing the active layer 30 may be performed by coating, for example, a mixed solution of an electron donor polymer and an electron acceptor polymer according to a solution process, e.g., spin coating and/or inkjet printing, and drying the same.

Providing the interlayer 40 may include applying a solution including the amphiphilic fullerene derivative on the first electrode 10 or the active layer 30 and drying the same.

The solution including the amphiphilic fullerene derivative may be prepared by dissolving the amphiphilic fullerene derivative in a solvent. The amphiphilic fullerene derivative has both the hydrophobic functional group and the hydrophilic functional group, so the amphiphilic fullerene derivative may be dissolved in various solvents. Because various solvents may be used, the scope of usable solvents is widened. The solvent may be, for example, chloroform, dichloromethane, xylene, toluene, benzene, chlorobenzene, dichlorobenzene, tetrahydrofuran, or a combination thereof, but is not limited thereto.

Applying a solution including the amphiphilic fullerene derivative may be performed by a method of, for example, spin coating, dip coating, slit coating, and/or inkjet printing, and the drying may be performed by, for example, drying at room temperature or heating at a temperature of greater than or equal to the boiling point of the solvent.

In applying the solution including the amphiphilic fullerene derivative, the amphiphilic fullerene derivative may be self-aligned by the difference of surface energy. Accordingly, when the amphiphilic fullerene derivative solution is applied on the first electrode 10, the side chains having lower polarity among the side chains of the amphiphilic fullerene derivative may be exposed to the external environment in order to minimize or reduce the surface energy, and the side chain having higher polarity may be aligned on the side of the first electrode 10.

Providing the interlayer 40 may further include a heat treatment. The heat treatment may be performed at a temperature of, for example, about 20° C. to about 150° C. By the heat treatment, the hydroxy group (—OH) disposed on the surface of the metal or metal oxide for the first electrode 10 and the hydrophilic functional group of the amphiphilic fullerene derivative may be condensed to further stabilize the interlayer 40.

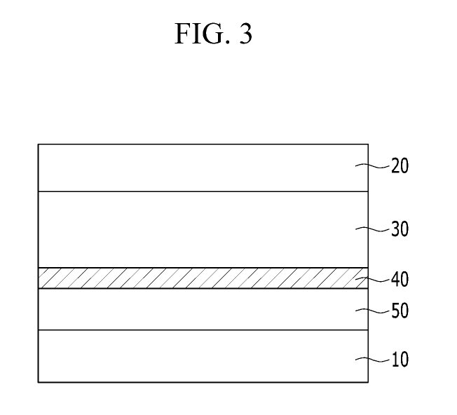

Hereinafter, the solar cell according to example embodiments is described with reference to FIG. 3. FIG. 3 is a schematic cross-sectional view of a solar cell according to example embodiments. Referring to FIG. 3, a solar cell includes a substrate (not shown), a first electrode 10, e.g., a cathode, a second electrode 20, e.g., an anode, facing the first electrode 10, an active layer 30 between the first and second electrodes 10 and 20, and an interlayer 40 between the first electrode 10 and the active layer 30, which are the same as in the above-described example embodiments.

However, the solar cell may further include a buffer layer 50 disposed between the first electrode 10 and the interlayer 40, differing from the above-mentioned example embodiments.

The buffer layer 50 may be made of, for example, a metal oxide, and the metal oxide may include, for example, zinc oxide (ZnO), titanium oxide (TiO₂), an alloy thereof, or a combination thereof. The buffer layer 50 may play a role of blocking the transportation of holes together with the interlayer 40 from the active layer 30 to the first electrode 10. Thereby, the charge recombination may be further reduced to improve the efficiency of a solar cell.

The method of manufacturing a solar cell according to example embodiments further includes providing the buffer layer 50 between the first electrode 10 and the interlayer 30.

The buffer layer 50 may be provided by, for example, deposition of a metal oxide or a solution process. The solution process may be, for example, a sol-gel method.

The interlayer 40 may be disposed on the buffer layer 50 or the active layer 30. When the interlayer 40 is disposed on the buffer layer 50, the interlayer 40 may include applying the solution including the amphiphilic fullerene derivative on the buffer layer 50 and heating the same. The heat treatment may be performed at about 20° C. to about 150° C.

By the heat treatment, the hydroxyl group (—OH) positioned on the surface of the metal oxide for the buffer layer 50 is condensed with the hydrophilic functional group of the amphiphilic fullerene derivative to further stabilize the interlayer 40.

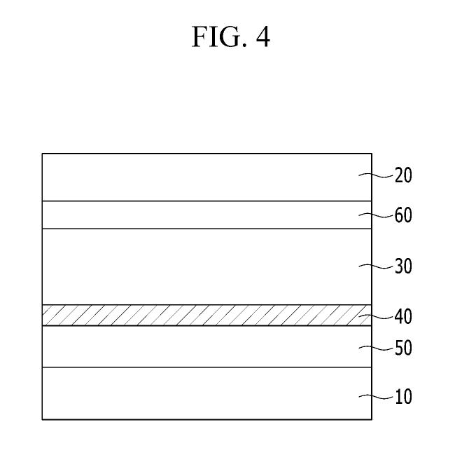

The solar cell according to example embodiments is described with reference to FIG. 4. FIG. 4 is a schematic cross-sectional view of a solar cell according to example embodiments. Referring to FIG. 4, a solar cell includes a substrate (not shown), a first electrode 10, e.g., a cathode, a second electrode 20, e.g., an anode, facing the first electrode 10, an active layer 30 between the first electrode 10 and the second electrode 20, and an interlayer 40 between the first electrode 10 and the active layer 30, which are the same as in the above-described embodiments.

However, the solar cell according to example embodiments includes a first buffer layer 50 between the first electrode 10 and the interlayer 40 similar to the example embodiments illustrated in FIG. 3, and a second buffer layer 60 between the second electrode 20 and the active layer 30, differing from the above-mentioned embodiments.

The buffer layer 60 be made of, for example, a metal oxide, and the metal oxide may be, for example, nickel oxide (NiO), tungsten oxide (WO₃), molybdenum oxide (MoO₃), vanadium pentoxide (V₂O₅), iridium oxide (IrO₂), ruthenium oxide (RuO₂), an alloy thereof, or a combination thereof.

The buffer layer 60 may play a role of blocking the electrons between the active layer 30 and the second electrode 20. Thereby, the efficiency of a solar cell may be improved.

Hereinafter, this disclosure is illustrated in more detail with reference to examples and comparative examples. However, these are example embodiments, and this disclosure is not limited thereto.

### Amphiphilic Fullerene Derivative

### Synthesis Example

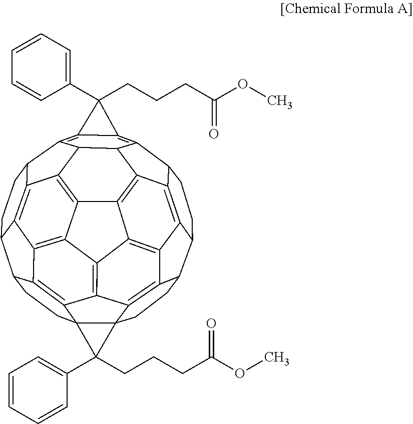 [SMILES: COC(=O)CCCC1(c2ccccc2)C2=C3C4CCC5c6c4c4c7c8c6c6c9c%10c%11c%12c%13c%14c%15c(c-7c%13c%108)C(C(=C21)C%15CCC%14C%12CCC%111C(CCCC(=O)OC)(c2ccccc2)C91CCC65)C34]

1 g of diphenyl-C₆₂-bis(butyric acid methylester) (manufactured by Sigma-Aldrich Co.) represented by Chemical Formula A is dissolved in 100 ml of toluene and added with 30 ml of concentrated HCl and 70 ml of acetic acid. The mixture is refluxed for 3 hours. After removing the solvent, the residue is precipitated in methanol and filtered. After cleaning with methanol, the residue is separated by column chromatography using an eluent of a mixture of ethylacetate and hexane to provide an amphiphilic fullerene derivative represented by the following Chemical Formula 1aa-1.

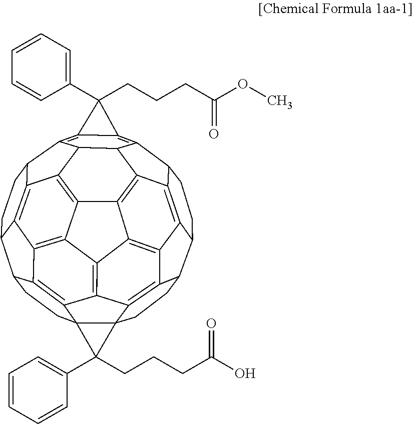 [SMILES: COC(=O)CCCC1(c2ccccc2)C2=C3C4CCC5c6c4c4c7c8c6c6c9c%10c%11c%12c%13c%14c%15c(c-7c%13c%108)C(C(=C21)C%15CCC%14C%12CCC%111C(CCCC(=O)O)(c2ccccc2)C91CCC65)C34]

Analysis

The products of the fullerene derivative before and after the column chromatography separation obtained from the synthesis example are observed using matrix-assisted laser desorption ionization time of flight (MALDI-ToF) mass spectroscopy.

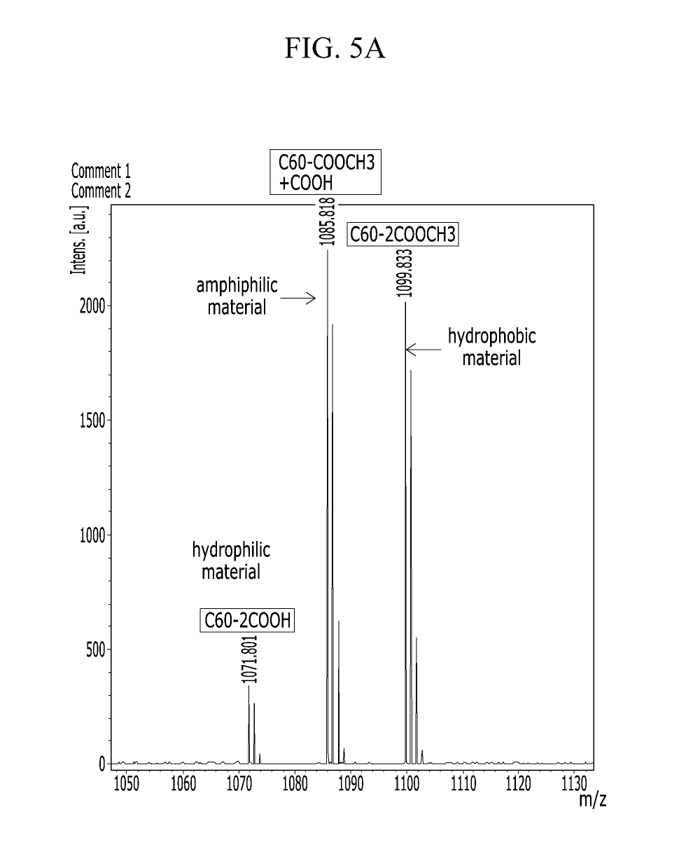

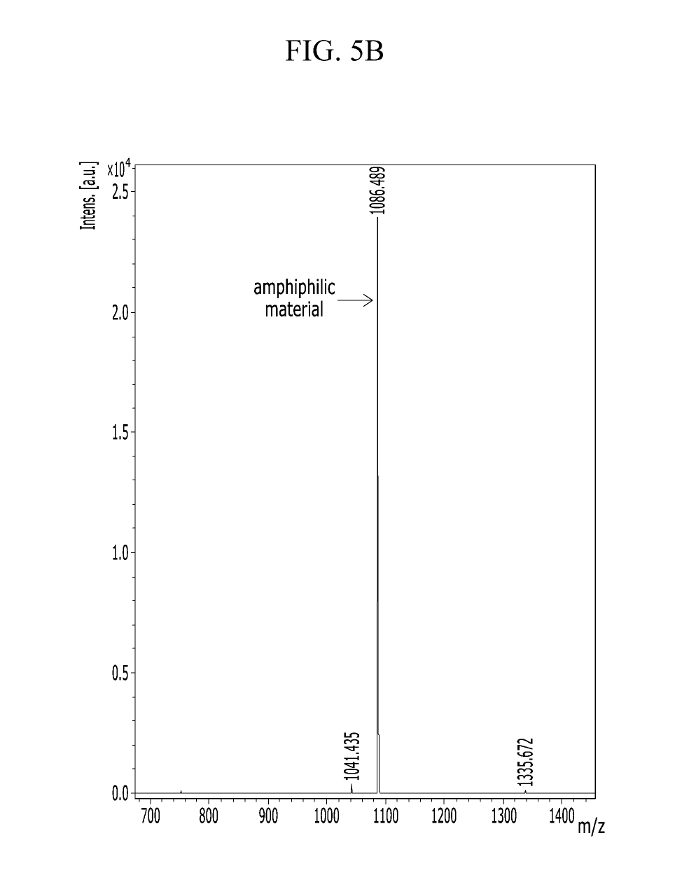

FIG. 5A is a MALDI-ToF analysis graph of the fullerene derivative product before the separation in the synthesis example, and FIG. 5B is a MALDI-ToF analysis graph of fullerene derivative product after the separation in the synthesis example.

Referring to FIGS. 5A and 5B, before the separation, the non-reacted hydrophobic fullerene derivative represented by the above Chemical Formula A is included together with the hydrophilic fullerene derivative represented by the following Chemical Formula B besides the amphiphilic fullerene derivative represented by above Chemical Formula 1aa-1; but, after the separation, only the amphiphilic fullerene derivative represented by the above Chemical Formula 1aa-1 may be selectively obtained.

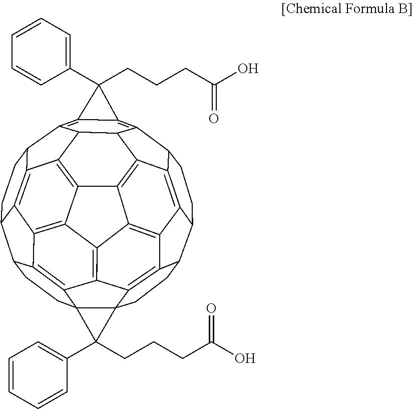 [SMILES: O=C(O)CCCC1(c2ccccc2)C2=C3C4CCC5c6c4c4c7c8c6c6c9c%10c%11c%12c%13c%14c%15c(c-7c%13c%108)C(C(=C21)C%15CCC%14C%12CCC%111C(CCCC(=O)O)(c2ccccc2)C91CCC65)C34]

### Manufacturing Solar Cell

### Example

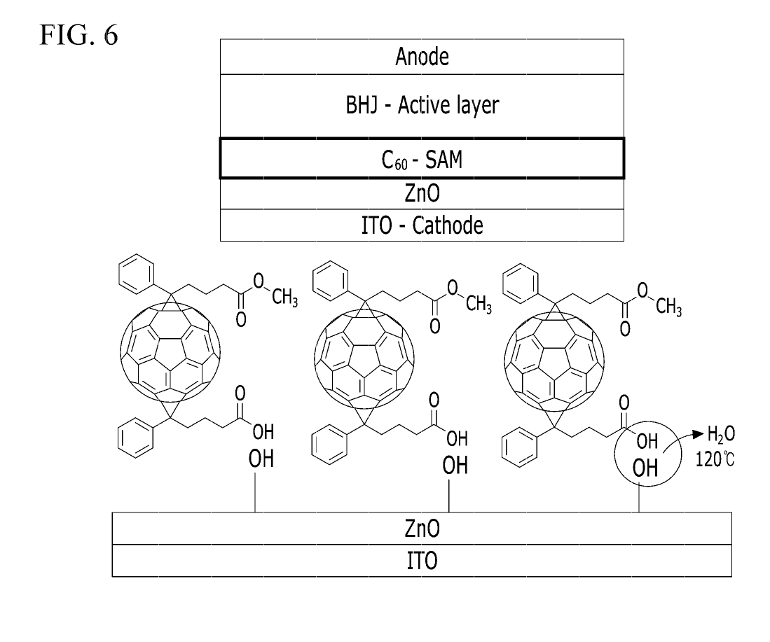

Referring to FIG. 6, a solar cell including the amphiphilic fullerene derivative obtained from Synthesis Example as an interlayer is described.

FIG. 6 is a schematic view of a solar cell according to examples. Indium tin oxide (ITO) is stacked on a transparent glass substrate according to a sputtering method to provide a cathode. A zinc precursor solution in which a zinc precursor of zinc acetate dihydrate and a catalyst of ethanolamine are dissolved in methoxyethanol is coated on the cathode according to spin coating and heated at 300° C. to provide a zinc oxide (ZnO) buffer layer.

The ZnO buffer layer is dip-coated in the solution in which the amphiphilic fullerene derivative obtained from the synthesis example is dissolved in toluene and dried. The ZnO buffer layer is heated at 120° C. such that the hydrophilic moiety of the amphiphilic fullerene derivative and the hydroxy group (—OH) of the ZnO buffer layer surface are chemically bonded by the condensation reaction to provide an interlayer (C₆₀-SAM).

A mixture including a p-type polymer of poly[(4,8-bis(5-(2-ethyl hexyl)thiophene-2-yl)benzodithiophene-2,6-diyl-alt-4-(ethoxycarbonyl)butyl-3-fluorothienothiophene-2-carboxylate-2,6-diyl] and an n-type polymer of phenyl-C71-butyric acid methyl ester (PCBM) is coated on the interlayer (C₆₀-SAM) according to spin coating to provide an active layer (BHJ-active layer). Subsequently, an MoO₃ layer and a silver (Ag) anode is disposed on the active layer (BHJ-active layer) to provide a solar cell.

### Comparative Example

A solar cell is fabricated in accordance with the same procedure as in the example, except that the interlayer is not provided.

Evaluation

The solar cells obtained from the example and comparative example are measured for a photocurrent voltage, and the short-circuit current density (Jsc) and the fill factor (FF) are calculated from the measured photocurrent curve. In addition, the efficiency (η) of the solar cell is evaluated.

The results are shown in Table 1.

TABLE 1

| | Jsc (mA/cm²) | FF (%) | η (%) |
|---|---|---|---|
| Example | 16 | 62 | 7.4 |
| Comparative | 15 | 61 | 6.6 |
| Example | | | |

Referring to Table 1, the solar cell according to the example has improved efficiency compared to the solar cell according to the comparative example.

While this disclosure has been described in connection with what is presently considered to be practical exemplary embodiments, it is to be understood that the inventive concepts are not limited to the disclosed embodiments, but, on the contrary, is intended to cover various modifications and equivalent arrangements included within the spirit and scope of the appended claims.

What is claimed is:

1. A solar cell comprising:
a first electrode;
a second electrode facing the first electrode;
an active layer between the first and second electrodes; and
an interlayer between the first electrode and active layer, the interlayer including an amphiphilic fullerene derivative.

2. The solar cell of claim 1, wherein the amphiphilic fullerene derivative is represented by the following Chemical Formula 1:
Z¹-A-Z² [Chemical Formula 1]
wherein, in Chemical Formula 1,
A is fullerene,
Z¹ is a side chain including a hydrophobic functional group, and
Z² is a side chain including a hydrophilic functional group.

3. The solar cell of claim 2, wherein the fullerene is represented by one of C₂ₙ (n≧110) and CₘHₚ (10≦m≦100, 10≦p≦100).

4. The solar cell of claim 2, wherein the Z¹ and Z² are positioned to be opposed to each other with respect to an axis of the fullerene.

5. The solar cell of claim 2, wherein the hydrophobic functional group has a polarity more than or equal to about 0 mN/m and less than or equal to about 5 mN/m, and the hydrophilic functional group has a polarity more than about 5 mN/m and less than or equal to about 50 mN/m.

6. The solar cell of claim 2, wherein the hydrophobic functional group includes one of a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, a halogen, a C₁ to C₃₀ ester group, a halogen-containing group, and a combination thereof.

7. The solar cell of claim 2, wherein the hydrophilic functional group includes one of a hydroxyl group, an acid group, a carboxylic acid group, a phosphoric acid group, an amino group, a sulfone group, an ammonium group, a substituted or unsubstituted C₁ to C₃₀ alkoxy group, and a combination thereof.

8. The solar cell of claim 2, wherein the amphiphilic fullerene derivative is represented by the following Chemical Formula 1a: 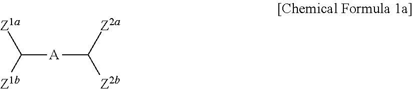
wherein, in Chemical Formula 1a,
A is fullerene,
each of Z^{1a} and Z^{2a} are independently one of a substituted or unsubstituted C₁ to C₃₀ alkyl group, a substituted or unsubstituted C₃ to C₃₀ cycloalkyl group, a substituted or unsubstituted C₆ to C₃₀ aryl group, and a substituted or unsubstituted C₂ to C₃₀ heteroaryl group,
Z^{1b} is a side chain including a hydrophobic functional group, and
Z^{2b} is a side chain including a hydrophilic functional group.

9. The solar cell of claim 8, wherein the amphiphilic fullerene derivative is represented by the following Chemical Formula 1aa: 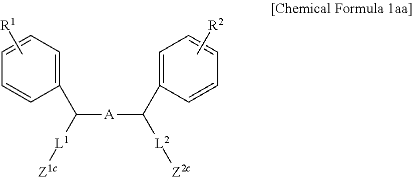
wherein, in Chemical Formula 1aa,
A is fullerene,
each of R¹ and R² are independently one of hydrogen, a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₂ to C₃₀ heteroaryl group, and a combination thereof,
each of L¹ and L² are independently one of a single bond, a substituted or unsubstituted C₁ to C₂₀ alkylene group, a substituted or unsubstituted C₃ to C₂₀ cycloalkylene group, a substituted or unsubstituted C₆ to C₃₀ arylene group, a substituted or unsubstituted C₂ to C₃₀ heteroarylene group, and a combination thereof,
Z^{1c} is a side chain including a hydrophobic functional group, and
Z^{2c} is a side chain including a hydrophilic functional group.

10. The solar cell of claim 2, wherein the amphiphilic fullerene derivative is self-aligned between the first electrode and the active layer.

11. The solar cell of claim 10, wherein Z¹ of the amphiphilic fullerene derivative is self-aligned on a side of the active layer, and
Z² of the amphiphilic fullerene derivative is self-aligned on a side of the first electrode.

12. The solar cell of claim 2, further comprising:
a buffer layer between the first electrode and the interlayer.

13. The solar cell of claim 12, wherein the buffer layer includes a metal oxide.

14. The solar cell of claim 13, wherein Z² of the amphiphilic fullerene derivative is chemically bonded with the metal oxide.

15. The solar cell of claim 1, wherein the first electrode is a cathode and the second electrode is an anode.

16. The solar cell of claim 1, wherein the first electrode is an anode and the second electrode is a cathode.

17. A method of manufacturing a solar cell, comprising:
providing a first electrode;
providing an active layer on the first electrode;
providing a second electrode on the active layer; and
providing an interlayer between the first electrode and the active layer, the interlayer including an amphiphilic fullerene derivative.

18. The method of claim 17, wherein the providing an interlayer provides an amphiphilic fullerene derivative represented by the below Chemical Formula 1:
Z¹-A-Z² [Chemical Formula 1]
wherein, in Chemical Formula 1,
A is fullerene,
Z¹ is a side chain including a hydrophobic functional group, and
Z² is a side chain including a hydrophilic functional group.

19. The method of claim 18, wherein the providing an interlayer includes applying a solution including the amphiphilic fullerene derivative on one of the first electrode and the active layer.

20. The method of claim 19, wherein the solution includes a solvent selected from chloroform, dichloromethane, xylene, toluene, benzene, chlorobenzene, dichlorobenzene, tetrahydrofuran, and a combination thereof.

21. The method of claim 19, further comprising:
heating the amphiphilic fullerene derivative at about 20° C. to about 150° C. after applying the solution.

22. The method of claim 18, further comprising:
providing a buffer layer after the providing a first electrode and before the providing an interlayer, the buffer layer including a metal oxide.

23. The method of claim 22, wherein the providing an interlayer includes:
applying a solution including the amphiphilic fullerene derivative on the buffer layer; and
heating the buffer layer including the applied solution at about 20° C. to about 150° C.,
wherein a condensation reaction of Z² of the amphiphilic fullerene derivative and the metal oxide is induced in the heating.

24. The solar cell of claim 17, wherein
the providing a first electrode includes providing a cathode; and
the providing a second electrode includes providing an anode.

25. The solar cell of claim 17, wherein
the providing a first electrode includes providing an anode; and
the providing a second electrode includes providing a cathode.
